(19) United States
(12) Patent Application Publication
(10) Pub. No.: US 2006/0091490 A1
(43) Pub. Date: May 4, 2006

(54) Self-aligned gated p-i-n diode for ultra-fast switching

(76) Inventors: Hung-Wei Chen, Hsinchu (TW); Wen-Chin Lee, Hsin-Chu (TW); Chih-Hsin Ko, Fongshan City (TW); Min-Hwa Chi, Taipei (TW); Chung-Hu Ke, Taipei (TW)

Correspondence Address: SLATER & MATSIL, L.L.P., 17950 PRESTON ROAD, SUITE 1000, DALLAS, TX, 75252, US

(21) Appl. No.: 11/077,478

(22) Filed: Mar. 10, 2005

Related U.S. Application Data
(60) Provisional application No. 60/624,631, filed on Nov. 3, 2004.

(51) Int. Cl. H01L 31/105

(52) U.S. Cl. 257/458

(57) ABSTRACT

A gated p-i-n diode and a method for forming the same. The gated p-i-n diode comprises: a semiconductor substrate; a gate dielectric over the semiconductor substrate; a gate electrode on the gate dielectric; a source gate spacer and a drain gate spacer along respective edges of the gate dielectric and the gate electrode; a source doped with a first type of dopant substantially under the source gate spacer wherein the source has a horizontal distance from a first edge of the gate electrode; a drain doped with the opposite type of the source substantially under the drain spacer and substantially aligned horizontally with a second edge of the gate electrode; a source silicide adjacent the source; and a drain silicide adjacent the drain.

This application claims the benefit of U.S. Provisional Application No. 60/624,631, filed on Nov. 3, 2004, entitled “Self-Aligned Gated p-i-n Diode,” which application is hereby incorporated herein by reference.

### CROSS-REFERENCE TO RELATED APPLICATIONS

This application relates to co-pending and commonly assigned patent application Ser. No. ______ (TSM04-0925), filed concurrently herewith, entitled “Multi-Level Flash Memory Cell Capable Of Fast Programming.”

### TECHNICAL FIELD

This invention relates generally to semiconductor devices, and more specifically to gated p-i-n diodes.

### BACKGROUND

Metal-oxide-semiconductor (MOS) is a dominating technology for integrated circuits at 90 nm technology and beyond. An MOS device can work in three regions depending on gate voltage V_{g} and source-drain voltage V_{ds}, linear, saturation and sub-threshold. Sub-threshold is a region where V_{g} is smaller than the threshold voltage Vₜ. The sub-threshold slope represents the easiness of switching the transistor current off and thus is an important factor in determining the speed of an MOS device. The sub-threshold slope can be expressed as a function of m*kT/q, where m is a parameter related to capacitance. The sub-threshold slope of typical MOS devices has a limit of about 60 mV/decade (kT/q), which in turn sets a limit for further scaling of operation voltage Vcc and Vₜ. This limit is due to the drift-diffusion transport mechanism of carriers. For this reason, existing MOS devices typically cannot switch faster than 60 mV/decade. The 60 mV/decade sub-threshold slope limit also applies to FinFET or ultra thin-body MOSFET on silicon-on-insulator (SOI) devices. Even with better gate control over the channel, an ultra thin body MOSFET on SOI or FinFET can only achieve a sub-threshold slope close to but never below the limit of 60 mV/decade. With such a limit, faster switching at low operation voltages for future nanometer devices cannot be achieved.

It has been realized that carrier transport based on a tunneling mechanism may offer faster switching. One example is an Schottky Source/Drain MOS device (as described in U.S. Pat. No. 5,177,568 by H. Honma), an example of which is illustrated in FIG. 1. Device 1 is a tunnel injection type semiconductor device comprising a channel region 20, a drain (silicide) 4, a gate electrode 12, and a source comprising metal silicide 6 and a doped semiconductor 8. Both source 6/8 and drain 4 have an overlapping portion with the gate electrode 12. The source 6/8 comprises a Schottky barrier junction between the metal silicide 6 and the semiconductor 8, which helps reducing leakage. The gate bias modulates the channel 20 and Schottky barrier to trigger tunnel current injection into the channel 20. The Schottky Source/Drain CMOS is a fast switching device. However, the 60 mV/decade limit is not exceeded.

FIG. 2 illustrates a prior art p-i-n diode having ultra-fast switching speed. The p-i-n diode has a heavily doped p-type region 30 and an n-type region 32 separated by an intrinsic region 33. A gate 38 is above the intrinsic region 33 to control the channel. The gated p-i-n diode has an offset channel region 34 between the source 30 and gate-edge 35. When the channel 36 underneath the gate is inverted by the gate bias, the drain-source voltage drops mainly across the offset region 34 and triggers avalanche breakdown. The “avalanche multiplication” during breakdown serves as an internal positive feedback, so that the sub-threshold slope can be greater than 10 mV/decade at very low drain voltage (for example, 0.2V). Such a gated p-i-n diode with avalanche mechanism for switching offers a promising approach for future MOS technology at 45 nm node and beyond.

The gated p-i-n diode of FIG. 2 suffers some drawbacks, however. Though it is capable of ultra-fast switching by avalanche mechanism, the critical width of the offset region Dₒ is sensitive to alignment errors between the gate and source/drain. This leads to large variations of electrical field in the offset region 34 during switching, which in turn leads to large variations of the sub-threshold slope. Furthermore, the avalanche mechanism of the prior art gated p-i-n diode is sensitive to temperature so that temperature variation also leads to sub-threshold slope variation. Therefore, there is a need for improved structures and manufacturing methods for reducing temperature sensitivity and alignment sensitivity of gated p-i-n diode in ultra-fast switching and low voltage operation.

### SUMMARY OF THE INVENTION

The preferred embodiment of the present invention presents a self aligned gated p-i-n diode and a method for forming such.

In accordance with one aspect of the present invention, a gate dielectric is formed on a substrate comprising a bulk silicon that is either lightly doped or un-doped. A gate electrode is formed over the gate dielectric. A pair of thin spacers is optionally formed. A tilt implant, also called drain implant, is performed to dope the drain with a first dopant. The tilt implant is tilted from the drain side and the implant regions reach into the first semiconductor for a first depth. A source spacer and a drain spacer are formed along the edges of the gate dielectric and the gate electrode. A source implant is performed to dope a source dopant opposite to the drain dopant type forming into a source. The source implant may be tilted from the source side or be vertical. Silicides are then formed on the source and the drain. The source and drain suicides preferably consume silicon to a depth not deeper than the drain implant.

When the drain is doped with n-type dopant and the source is doped with p-type dopant, the resulting gated p-i-n diode behaves similar to an NMOS. Conversely, when the drain is doped with p-type dopant and the source is doped with n-type dopant, the resulting gated p-i-n diode behaves similar to a pMOS. The gated p-i-n diode can be combined with a conventional MOSFET to achieve faster switching.

In accordance with another aspect of the present invention, the gate dielectric is formed on lightly doped or un-doped silicon. Since SiGe has lower energy band gap that results in lower avalanche breakdown voltage, it is desired to incorporate germanium into silicon to achieve low operation voltage. SiGe regions can be formed by either epitaxy or implantation. In the approach of SiGe epitaxy, the regions designated for SiGe epitaxy is recessed by etching, then followed by epitaxy to form symmetric SiGe regions. In addition, Ge can be implanted symmetrically, which is tilt implanted from both the source and the drain side, or asymmetrically, which is tilt implanted from the source side only.

In accordance with yet another aspect of the present invention, a p-i-n diode can be formed on buried oxide. Silicon or germanium containing materials such as Si, SiGe, Ge or SiGeC can be used in the source, the drain and the channel area.

The present embodiments of the present invention have several advantageous features. First, the preferred embodiments use spacers and tilt implanting to control the alignment of the source and drain formation. The formation of the offset region is more precise to that the avalanche breakdown mechanism is better controlled. Second, the self-aligned gated p-i-n diode fabrication can be combined with current CMOS manufacturing process. The combined circuits are faster for switching. Third, the self-aligned gated p-i-n diode can be operated at low voltage (<0.5V) with ultra-fast sub-threshold swing (<10 mV/decade). The performance is superior to state-of-the-art CMOS transistors. Fourth, the offset region may be doped to a medium level, so that both avalanche and band-to-band tunneling mechanisms occur simultaneously and the temperature sensitivity of the gated p-i-n diode is minimized.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional Schottky Source/Drain MOS device;

FIG. 2 illustrates a prior art gated p-i-n diode having ultra-fast switching speed;

FIGS. 3 through 10 are cross-sectional views of intermediate stages in the manufacture of an n-channel self-aligned gated p-i-n diode;

FIG. 11 illustrates offset and inversion regions of an n-channel self-aligned gated p-i-n diode;

FIG. 12 illustrates an energy band diagram of an n-channel self-aligned gated p-i-n diode at “off” state;

FIG. 13 illustrates an energy band diagram of an n-channel self-aligned gated p-i-n diode at “on” state;

FIG. 14 illustrates a p-channel self-aligned gated p-i-n diode;

FIG. 15 illustrates an energy band diagram of a p-channel self-aligned gated p-i-n diode at “off” state; and

FIG. 16 illustrates an energy band diagram of a p-channel self-aligned gated p-i-n diode at “on” state.

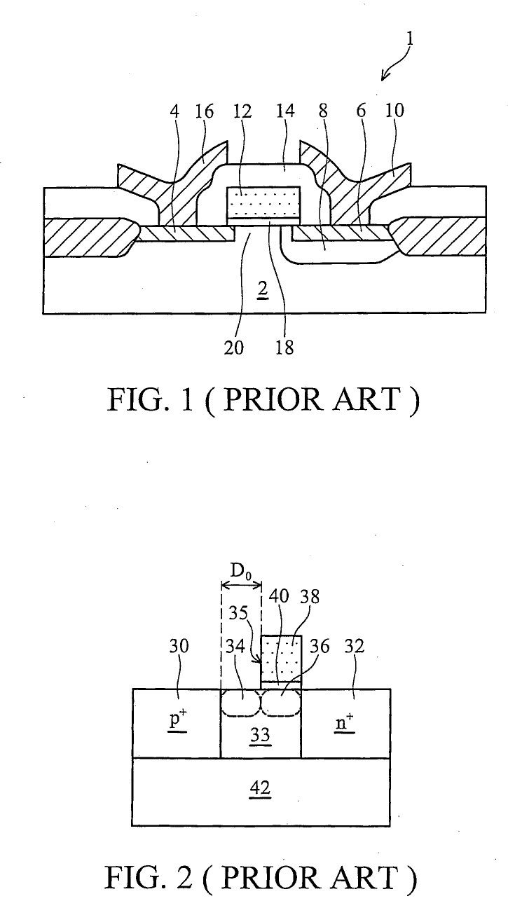

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A manufacturing process of a preferred embodiment of the present invention is discussed. Variations of the preferred embodiments are presented. Like reference numbers are used to designate like elements throughout the various views and illustrative embodiments of the present invention. Each figure number may be followed by a letter A, B or C showing variations of the same process step.

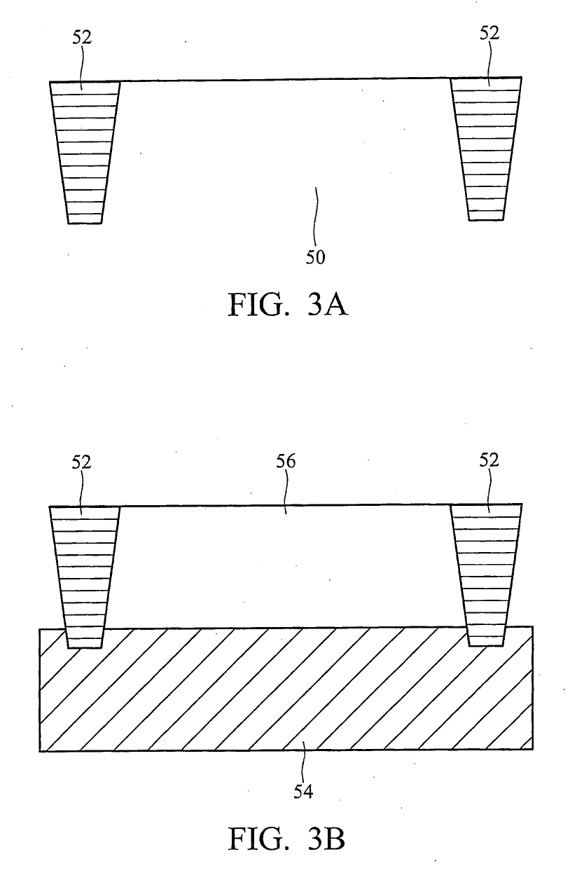

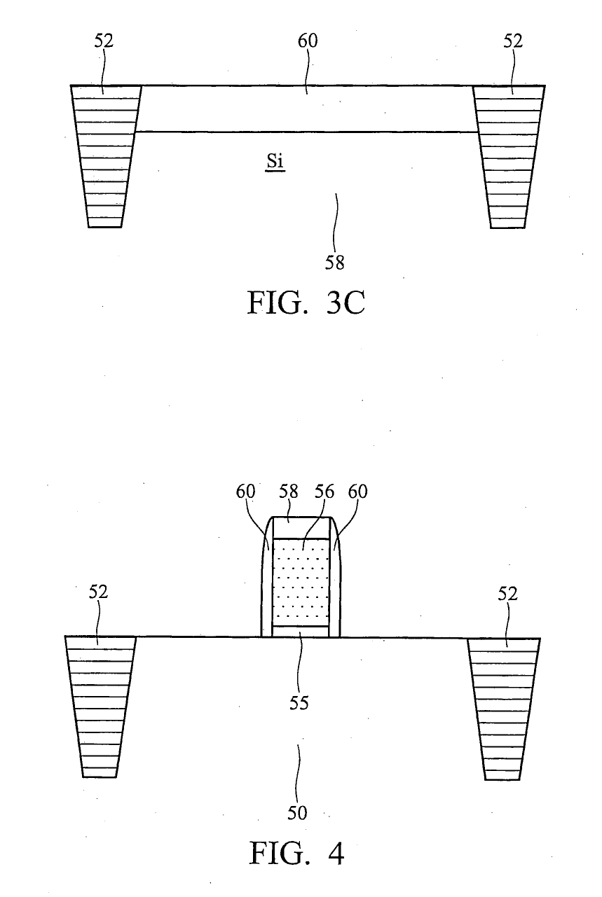

FIGS. 3 through 10 illustrate a preferred embodiment of a gated p-i-n diode of the present invention. FIG. 3A illustrates shallow trench isolations (STI) 52 formed in a substrate 50. The STIs 52 are preferably formed by etching shallow trenches in substrate 50, and filling the trenches with an insulator such as silicon oxide. In one embodiment, substrate 50 is a bulk material such as Si. In alternative embodiments, substrate 50 may have a structure of silicon-on-insulator (SOI), as illustrated in FIG. 3B. Preferably, the insulator, or buried oxide (BOX) 54 has a thickness of between 10 nm and about 200 nm, and the silicon layer 56 on the buried oxide has a thickness of about 2 nm to about 200 nm. It is preferred that the thickness of the silicon on the buried oxide 54 is less than the depth of the STI 52, so that STI 52 may reach the top surface of the buried oxide 54. In a more preferred embodiment, bulk SiGe, bulk germanium (Ge), SiGe on insulator, or Ge on insulator is used as substrate 50 or 56. SiGe has several advantageous features. Since SiGe has a smaller band gap and therefore a lower avalanche breakdown field than Si, it is particularly suitable for the gated p-i-n diode employing the avalanche mechanism. With lower avalanche breakdown field, device reliability is improved since hot carriers energy is lowered. Also, devices with SiGe in the source and drain regions can induce compressive stress on the device channel and further enhance the avalanche mechanism. SiGe is preferably epitaxially grown in a chamber having pressure of about 1 mTorr to about 100 Torr and grown to a thickness of between about 2 nm and about 100 nm. The resulting Ge content is preferably between about 10% and about 80%. SiGe may also have a graded buffer structure, as illustrated in FIG. 3C. A SiGe layer 60 is formed on a bulk Si substrate 58 so that the p-i-n diode formed on this structure has SiGe 60 in its channel region.

FIG. 4 illustrates the formation of a gate structure. As is known in the art, a gate dielectric layer 55 is first formed on substrate 50, followed by a gate electrode layer 56. These layers are then patterned and etched to form the gate electrode 56 and gate dielectric 55. Gate dielectric 55 may comprise silicates such as HfSiO₄, HfSiON, HfSiN, ZrSiO₄, ZrSiON, and ZrSiN, or metal oxides, such as Al₂O₃, ZrO₂, HfO₂, Y₂O₃, La₂O₃, TiO₂, and Ta₂O₅. Other materials such as oxides comprising SiO₂ and oxynitride can also be used. In some embodiments, gate electric may be a composite of one or more layers of one or more of the above materials.

Gate electrode 56 may be polysilicon or poly-SiGe that is doped with the same dopant type as the drain, which will be formed in subsequent steps. Since the threshold voltage is a function of the work function of the gate 56, by changing the doping of gate electrode 56, the work function can be changed, and the threshold voltage of the device is also changed. When the poly gate electrode 56 is doped with the opposite type dopant as the drain, the threshold voltage can be significantly lowered. Assuming the channel material has a band gap E_{g}, and further assuming inversion voltage Vᵢₙᵥ is to be applied in order to turn on the device and invert the region under the gate, if the poly gate 56 is doped with the opposite dopant type as the drain, the inversion voltage becomes Vᵢₙᵥ−E_{g}. Therefore it is easier to turn on the device and switching is thus faster. For example, silicon has an E_{g} of about 1.12V, germanium has an E_{g} of about 0.7V, and SiGe has an E_{g} of between 0.7 and 1.12V. Therefore, the threshold voltage of the device can be lowered significantly. The work function of the gate electrode 56 can also be changed by forming metal or metal silicide gate. Gate electrode 56 may be formed of metal or metal alloys comprising ruthenium, titanium, tantalum, tungsten, hafnium and combinations thereof, or metal oxide comprising RuO₂, IrO₂, and combinations thereof. Metal gate electrode 56 may also comprise metal nitrides. By adjusting the material of the gate electrode 56 and/or its doping type, suitable threshold voltage can be obtained.

A hard mask 58 is formed on the gate electrode 56 to protect it from being implanted in subsequent steps. FIG. 4 also illustrates thin spacers 60 optionally formed along the sidewalls of the gate dielectric 54 and gate electrode 56. Thin spacers 60 serve as self-aligning masks for subsequent drain formation steps and help to reduce implant damage to the gate dielectric 54 and gate electrode 56, as described below. The spacers 60 may be formed by well-known methods such as blanket depositing a dielectric layer over the entire region, then anisotropically etching to remove the dielectric from the horizontal surfaces and leaving thin spacers 60. Thin spacers 60 preferably have a thickness of between about 1 nm and about 30 nm.

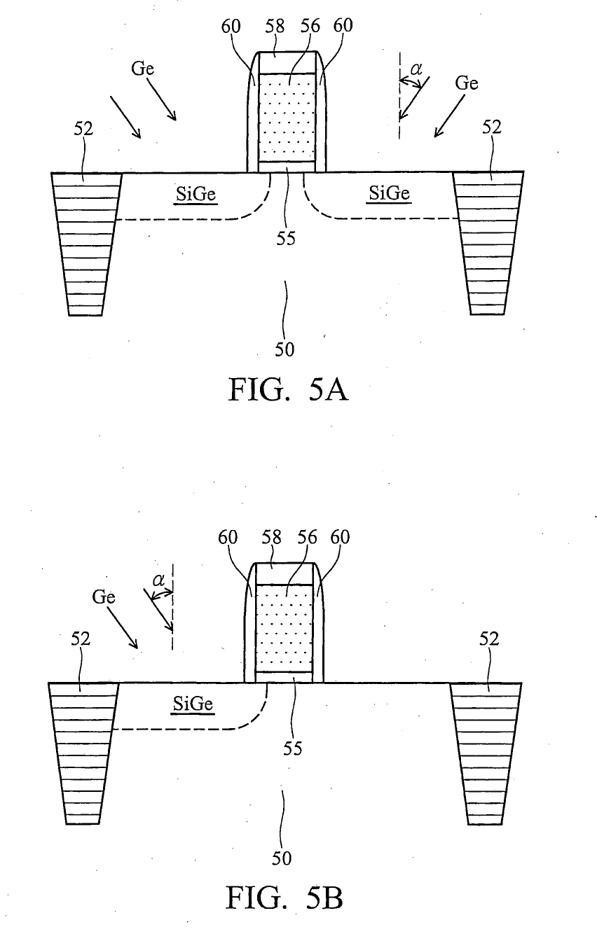

In the case where substrate 50 is silicon, Ge is preferably implanted into the source, drain and offset regions, as will be discussed in subsequent paragraphs, due to its ability to lower the band gap. In FIG. 5A and FIG. 5B, the p-i-n diode is formed on a silicon substrate 50, and Ge is implanted to form SiGe. In the preferred embodiment, Ge may be implanted to a dosage of between about 1E15/cm² to about 1E17/cm². It is preferred that the SiGe extends to the region under the gate 56. The tilt angle α is preferably between about 0° to about 45°. Ge may be implanted symmetrically or asymmetrically. FIG. 5A illustrates a symmetrical implanting. Ge is tilt implanted from both directions so that SiGe extends under the gate from both source and drain sides. In other embodiments, Ge can be implanted only from the source side so that an asymmetric structure is formed, as illustrated in FIG. 5B. Since avalanche occurs on the source side, lowering the band gap of the source material is sufficient to improve avalanche performance. After Ge implant, an annealing step is performed to restore the lattice structure before dopants are implanted.

SiGe may also be formed in source/drain/offset regions by forming recesses in these regions, and then epitaxially growing SiGe in the recesses. Epitaxy may be performed in a chamber having pressure of about 1 mTorr to about 100 Torr. The desired SiGe thickness is between about 2 nm and about 100 nm. The resulting Ge content is preferably between about 10% and about 80%.

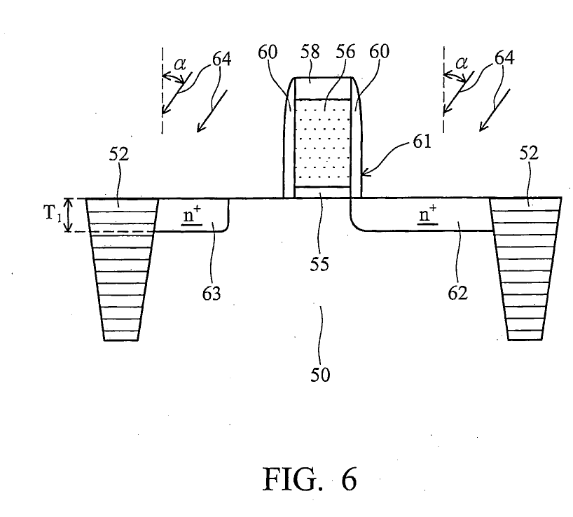

FIG. 6 illustrates a shallow tilted n+ implant, also called a drain implant employed to form a drain 62. The implant is symbolized by arrows 64. The shallow n+ implant preferably has a dosage of from about 1E15/cm² to about 1E16/cm². Preferably, the tilt angle α is between about 0° and 45°, and the depth T₁ of the shallow implant regions 62 and 63 is between about 5 nm and about 50 nm. By using thin spacer 60 as an implant mask, the shallow implant region 62, which will be the drain, can easily be aligned with the boundary 61 of the gate electrode 56 or slightly recessed from the boundary. Since implanting is tilted, the thin spacer 60 on the drain side is also doped, thus becomes more porous than the spacer 60 on the source side and thus has a higher etching rate. Therefore, the thin spacer 60 on the drain side may be etched more than the spacer 60 on the source side in the subsequent steps. The resulting device may have a thicker spacer 60 on the source side than on the drain side.

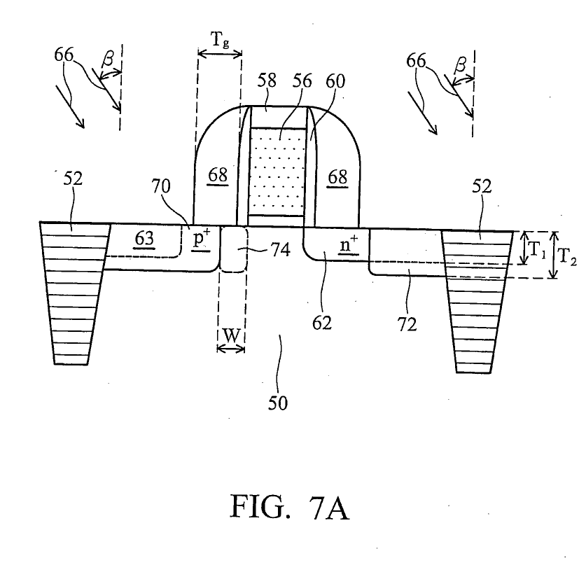

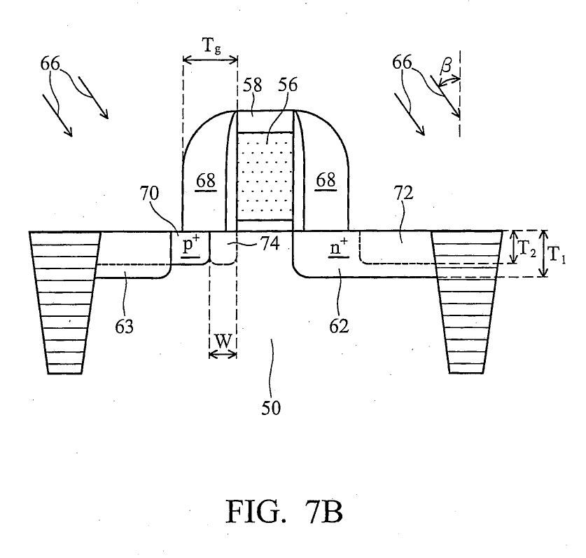

A pair of gate spacers 68 are then formed and a p+, or source implant, is performed, as illustrated in FIGS. 7A and 7B. The source implant is symbolized by arrows 66. The thickness T_{g} of the gate spacers 68 is preferably between about 5 nm and about 100 nm. The source implant uses spacers 68 as a mask and may be performed either tilted, which is illustrated in FIG. 7A, or vertically, where the tilt angle β with reference to FIG. 7A is 0°. If tilted, the tilt angle β is preferably between about 0° and about 45°. The depth T₂ of the source implant, or p+ implant regions 70 and 72 is preferably greater than the depth T₁ of the shallow implant regions 62 and 63, and is preferably between about 5 nm and about 70 nm. Typically, the implant depth T₂ is affected by the tilt angle and implant energy. The implant dosage is preferably between about 1E15/cm² and 1E16/cm². Deeper p+ regions are preferred since the resulting device will have reduced leakage through the bulk region 50 due to the Schottky barrier formed in the subsequent steps. However, due to process errors (or possibly due to intentional design constraints), p+ regions 70 and 72 may actually be shallower than n+ regions 62 and 63, and the resulting structure is illustrated in FIG. 7B.

Referring to FIGS. 7A and 7B, the source side p+ region 70 is spaced from the gate boundary and an offset region 74 is formed. The offset region 74 is the region where avalanche breakdown occurs. Since most of the drain-source voltage is applied to the offset region when the device is turned on, the lesser the width W is, the higher the electrical field will be, and the easier avalanche breakdown will occur. Width W of the offset region 74 is controlled carefully by controlling process parameters such as the implant angle β, the thickness of spacers 68, etc. Due to the self-alignment of the spacers 68, the width W of the offset region 74 is easier to control than conventional approaches. In an exemplary embodiment, the width W is between about 2 nm and about 50 nm.

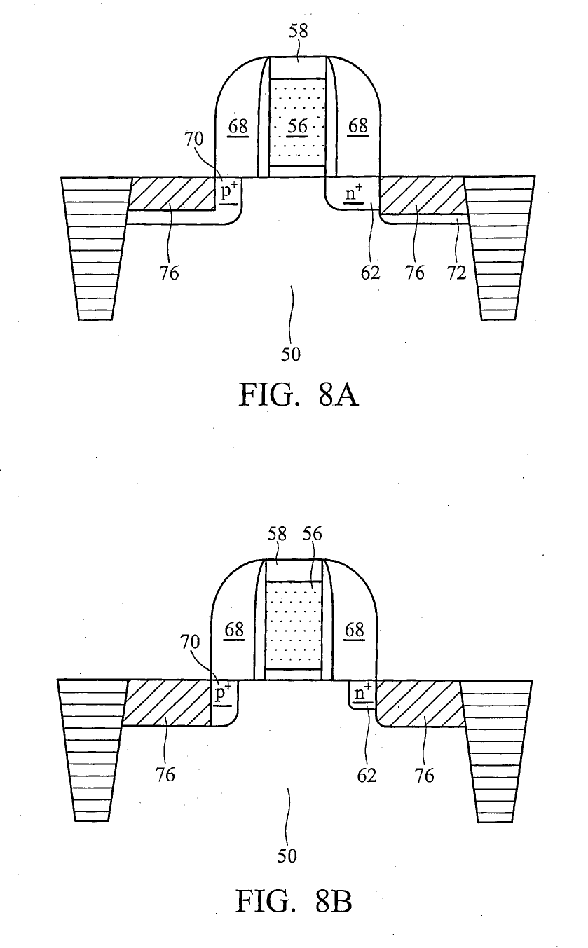

FIGS. 8A and 8B illustrate the formation of silicide 76. To form a silicide layer, a metal layer is formed by first depositing a thin layer of metal, such as cobalt, nickel, erbium, molybdenum, platinum, or the like, over the device. The device is then annealed to form a silicide between the deposited metal and the underlying exposed silicon regions. After silicidation, the shallow n+ implant region 63 on the source side with reference to FIG. 7A is fully consumed and the deeper implant region 70 encloses the silicide 76. The remaining part under the spacer 68 forms a source 70, as illustrated in FIG. 8A. If the deep p+ implant is not fully consumed, the source 70 extends to the bottom of the silicide 76, as shown in FIG. 8A. On the drain side, the n+ region uncovered by spacer 68 is fully or substantially fully consumed, and the portion under the gate spacer 68 forms a drain 62. In the case where the p+ region 72 is deeper than n+ region 62, as referred in FIG. 8A, a Schottky barrier formed between the interface of metal silicide 76 and semiconductor 72 helps to reduce leakage current. In the case where the p+ region 72 is shallower than n+ region 62, as referred in FIG. 8B, p+ region 72 on the drain side is fully consumed.

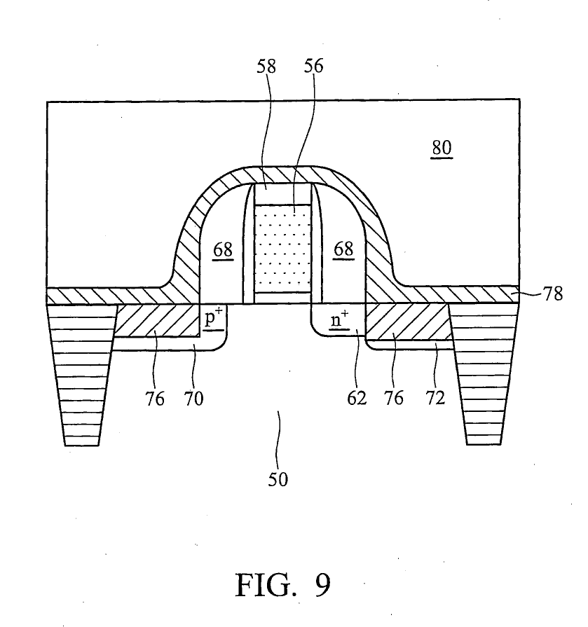

The previous steps have shown the formation of a gated p-i-n diode. FIG. 9 illustrates the formation of a contact etch stop layer 78 (CESL) and an inter-layer dielectric (ILD) 80. CESL 78 is blanket deposited to cover the whole device, including source, drain, and gate. This layer serves two purposes. First, it provides a stress to the device and enhances carrier mobility. Second, it acts as a contact etch stop layer to protect underlying regions from being over etched. As known in the art, the etching stop layer needs to have sufficient thickness to provide enough stress. It preferably has a thickness of from about 10 nm to about 150 nm. Next, an inter-layer dielectric (ILD) 80 is deposited over the surface of CESL 78. The ILD 80 preferably comprises a low dielectric constant material and has a thickness of between 100 nm to about 1000 nm. ILD 80 preferably also contributes to the stress to the device channel. The process-induced stress from either CESL or ILD contributes to strain-induced band gap narrowing and thus could lead to lower avalanche breakdown voltage.

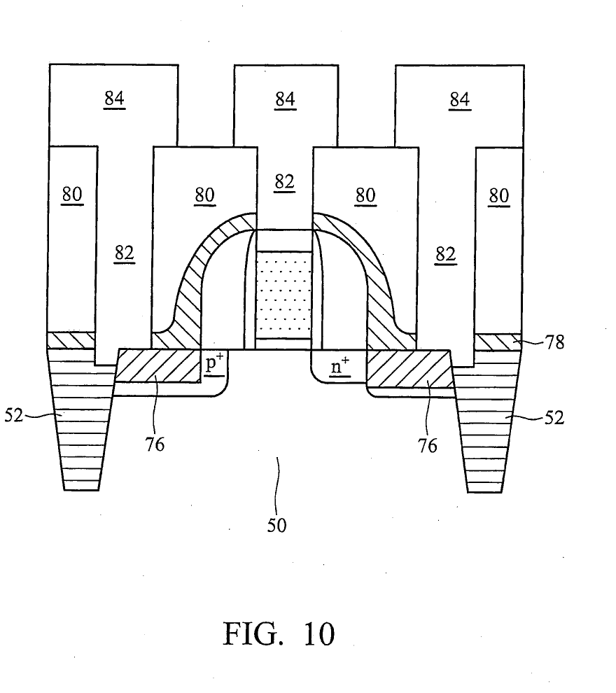

FIG. 10 illustrates a complete structure of the device after the contact plugs 82 and a metal interconnect 84 are made. The process of forming contact plugs 82 and metal layer 84 are well known in the art and therefore are not repeated herein. In the preferred embodiment where faster and smaller devices are desired, the metal plugs 82 have a borderless structure and reside partially on the silicide 76. This structure requires less area of silicide 76. Therefore, the resulting integrated circuit is more compact. In other embodiments, bordered contacts, where metal contacts reside fully on silicide 76 can be formed.

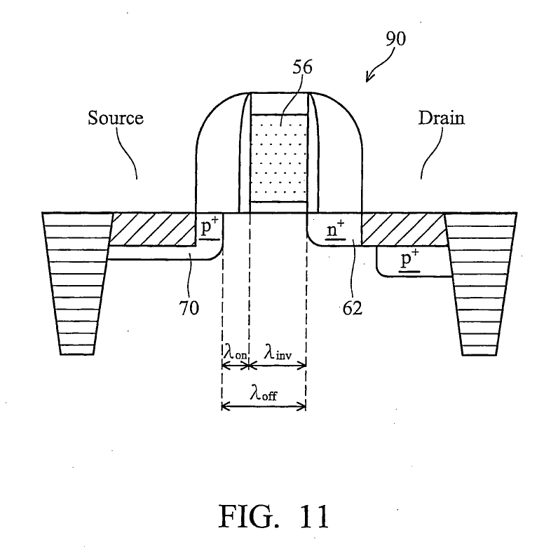

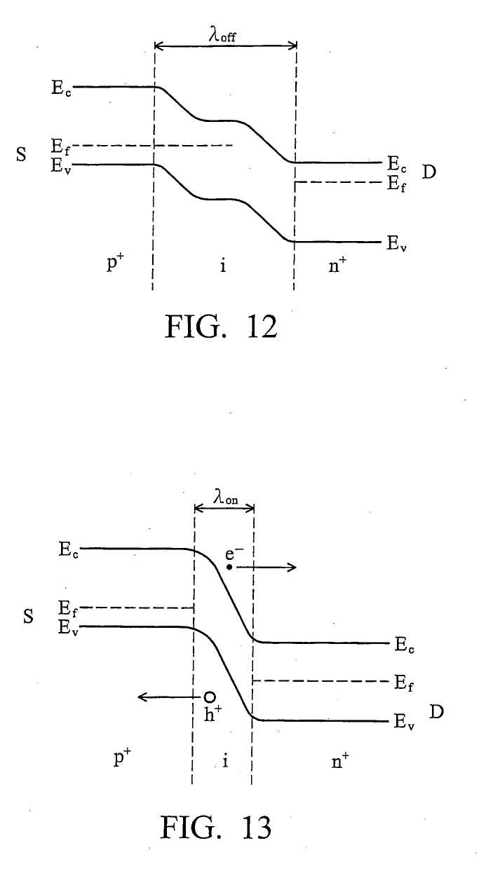

FIG. 11 illustrates inversion and offset regions of a gated p-i-n diode formed in the previously discussed embodiment. A device in the “off” state has a depletion region length of λ_{off}, and a device in the “on” state has a depletion region length of λₒₙ. When the diode 90 is turned off, for example, its gate voltage V_{g} is 0V, source voltage Vₛ is 0V and drain voltage V_{d} is higher than the source voltage Vₛ, the depletion region has a length λ_{off}. FIG. 12 illustrates an energy band diagram of the device 90 at “off” state. The left side is the energy band of the p+ region 70. The right side is the energy band of the n+ region 62. When the diode 90 is turned on, for example, its gate voltage V_{g} is Vcc, source voltage Vₛ is 0V and drain voltage V_{d} is higher than the source voltage Vₛ. As a result, the channel under gate 56 is inverted and therefore the depletion region has a length λₒₙ, which equals λ_{off}−λᵢₙᵥ, where λᵢₙᵥ is the length of the inversion region under the gate. FIG. 13 illustrates an energy band diagram of the device 90 at “on” state. Since most of the drain voltage is applied to the narrow depletion region λₒₙ, the electrical field in the depletion region is much stronger and avalanche breakdown occurs.

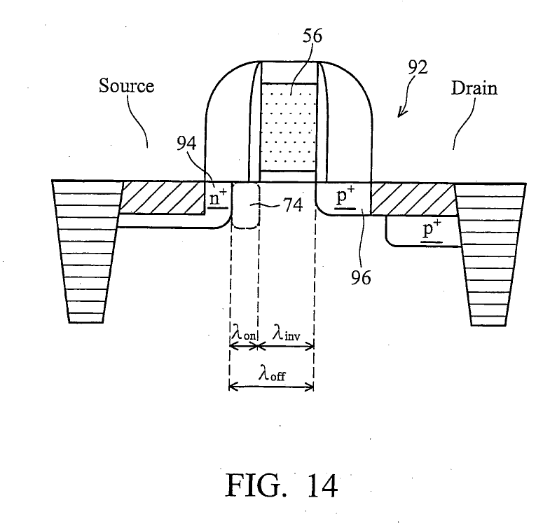

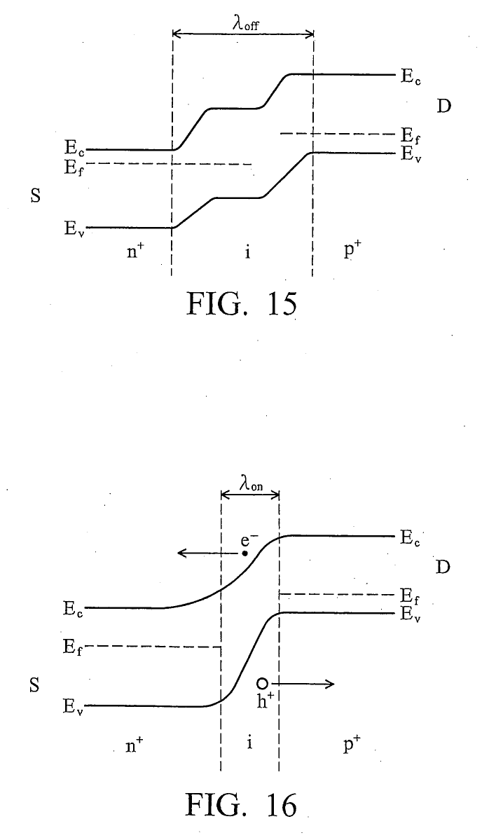

FIG. 14 illustrates another preferred embodiment having a p-channel. The specification for forming the p-channel gate diode 92 is similar to what is specified for circuit formation of an n-channel p-i-n diode 90, except the p and n types are reversed and materials are changed correspondingly. FIG. 14 also illustrates the depletion regions λ_{off} and λₒₙ when the device is at “off” or “on” state respectively. When the diode 92 is turned off, for example, its gate voltage V_{g} equals source voltage Vₛ, and drain voltage V_{d} is lower than the source voltage Vₛ. As a result, the channel under the gate 56 is depleted. FIG. 15 illustrates an energy band diagram of the device 92 in the “off” state. The left side is the band of the n+ region 94, the right side is the band of the p+ region 96, and the depletion region has a greater length λ_{off}. Diode 92 is turned on, for example, when its gate voltage V_{g} equals −Vcc, source voltage Vₛ is 0V and drain voltage V_{d} is lower than the source voltage Vₛ. As a result, the channel under gate 56 is inverted and, therefore, the depletion region has a length λₒₙ, which is smaller than λ_{off}. FIG. 16 illustrates an energy band diagram of a device at “on” state. Since most of the drain voltage is applied to the narrow depletion region with a length λₒₙ, the electrical field in depletion region is stronger thus avalanche breakdown occurs. In the preferred embodiments of the present invention, avalanche and band-to-band tunneling may co-exist. The avalanche and band-to-band tunneling have positive and negative temperature coefficients, respectively. In lightly doped or un-doped offset region 74 (sometimes also referred to as the intrinsic region), the avalanche effect dominates since the band-to-band tunneling is not likely to be triggered. If the doping in the offset region increases to a medium level, for example, about 1E16 to about 1E17/cm³, both avalanche and band-to-band tunneling may coexist and the preferred embodiments have much smaller temperature sensitivity. Functionally, the preferred embodiments of the present invention are similar to MOSFETs and can be integrated with conventional CMOS circuits. The operation of an n-channel gated p-i-n diodes is similar to an n-MOSFET, and the operation of a p-channel gated p-i-n diodes is similar to a p-MOSFET. A pair of n-channel and p-channel gated p-i-n diodes can function as an inverter (similar to a conventional CMOS inverter). Either an n-channel or a p-channel p-i-n diode may be connected in series with a conventional pMOS device or a conventional NMOS device respectively to function as an inverter. Logic gates and circuits can be formed entirely of p-i-n diodes or as a combination of gated p-i-n diodes and conventional MOS devices. Gated p-i-n diodes using SiGe S/D can also be optionally fabricated with other gated p-i-n diodes without SiGe S/D (either n-channel or p-channel) by using extra masking steps for Ge implanting. The preferred embodiments use spacers and tilt implanting to control the self-aligned formation of the source and drain. The preferred embodiments of the present invention have several advantageous features. First, the formation of the offset region is precise and thus the avalanche breakdown mechanism is better controlled. Second, the self-aligned gated p-i-n diode can be fabricated with CMOS processes for robust manufacturing and the new devices may be selectively fabricated with conventional CMOS together on one chip (with extra masking steps and implants). Third, the self-aligned gated p-i-n diode can be operated at low voltage (<0.5V) with ultra-fast sub-threshold swing (<10 mV/decade). The performance is superior to typical state-of-the-art CMOS transistors. This is possibly due to the narrow and self-aligned offset width for triggering avalanche breakdown. The n-channel and p-channel gated p-i-n diodes may be operated similarly to conventional n-MOS and p-MOS transistors, respectively, from circuit point of view. Fourth, the offset region may be doped to a medium level, so that both avalanche and band-to-band tunneling mechanisms occur simultaneously. Due to avalanche and band-to-band tunneling having opposite temperature coefficients, the p-i-n diode's temperature sensitivity is minimized.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a semiconductor substrate;
a gate dielectric over the semiconductor substrate;
a gate electrode over the gate dielectric;
a source gate spacer and a drain gate spacer along respective edges of the gate dielectric and the gate electrode;
a source doped with a first type of dopant extending substantially under the source gate spacer and laterally spaced apart from a first edge of the gate electrode; and
a drain doped with a second type of dopant, opposite from the first type, the drain being substantially under the drain spacer and substantially aligned with a second edge of the gate electrode.

2. The semiconductor device of claim 1 further comprising:
a source silicide adjacent the source; and
a drain silicide adjacent the drain.

3. The semiconductor device of claim 2 wherein the semiconductor substrate further comprises a region under the drain silicide and doped with a dopant of the first type.

4. The semiconductor device of claim 2 wherein the source extends under the source silicide.

5. The semiconductor device of claim 1 wherein the semiconductor substrate is lightly doped having a dopant concentration of less than about 1E15/cm³.

6. The semiconductor device of claim 1 wherein the semiconductor substrate is un-doped.

7. The semiconductor device of claim 1 wherein the semiconductor substrate is silicon locally modified by implanting Ge at an angle of between about 0° and 45°.

8. The semiconductor device of claim 1 wherein the semiconductor substrate is on a buried oxide.

9. The semiconductor device of claim 8 wherein the semiconductor substrate has a thickness of between about 2 nm and about 200 nm and the buried oxide has a thickness of between about 10 nm and about 200 nm.

10. A method of forming a semiconductor device, the method comprising the steps of:
providing a semiconductor substrate;
forming a gate dielectric over the semiconductor substrate;
forming a gate electrode over the gate dielectric;
tilt implanting a drain dopant of a first type, to a first depth to form a drain, the tilt implanting being tilted from the drain side of the gate electrode;
forming a source spacer and a drain spacer along respective edges of the gate dielectric and the gate electrode; and
implanting a source dopant of a second type opposite to the first type to form a source.

11. The method of claim 10 further comprising the step of forming a source silicide on the source and a drain silicide on the drain.

12. The method of claim 11 wherein forming the source silicide and the drain silicide consumes silicon on the source and drain respectively to a second depth no more than the first depth.

13. The method of claim 10 wherein the source dopant implanting is tilted from a source side at an angle of between about 0° and about 45°.

14. The method of claim 10 further comprising the step of implanting Ge into the semiconductor substrate.

15. The method of claim 14 wherein the Ge implanting is symmetrical and Ge is tilt implanted from both the source side and the drain side.

16. The method of claim 14 wherein the Ge implanting is asymmetrical and only from the source side.

17. The method of claim 14 wherein the Ge implant has a dosage of between about 1E15/cm² and about 1E17/cm².

18. The method of claim 10 wherein the semiconductor substrate comprises SiGe and is formed epitaxially to a thickness of about 2 nm to about 200 nm.

19. The method of claim 18 wherein the semiconductor substrate is epitaxially grown in a chamber having a pressure of about 1 mTorr to about 100 Torr.

20. The method of claim 10 further comprising the step of forming a pair of thin spacers along respective edges of the gate electrode and gate dielectric before implanting the drain dopant.

21. The method of claim 20 wherein each of the thin spacers has a thickness of between about 1 nm and about 30 nm.

22. The method of claim 10 wherein the source spacer and the drain spacer each has a thickness of between about 5 nm and about 100 nm.

23. The method of claim 10 wherein the source spacer is thicker than the drain spacer.

24. The method of claim 10 wherein implanting the drain dopant is at a tilt angle of between about 0° and 45°.

25. A transistor comprising:
a semiconductor substrate;
a first region at a surface of the semiconductor substrate doped with impurities of a first conductivity;
a second region at the surface of the semiconductor substrate doped with impurities of a second conductivity;
the first and second regions defining therebetween a channel region along the surface of the semiconductor substrate;
a gate overlying a portion, but not all, of the channel region, wherein the first region is substantially aligned with a first sidewall of the gate and the second region is laterally spaced apart from a second sidewall of the gate;
a first gate spacer substantially above the first region; and
a second gate spacer substantially above the second region.

26. The transistor of claim 25 further comprising a first silicide adjacent the first region and a second silicide adjacent the second region wherein the first silicide has an edge substantially aligned with an edge of the first gate spacer, and wherein the second silicide has an edge substantially aligned with an edge of the second gate spacer.

27. The transistor of claim 25 wherein the first gate spacer comprises a first thin spacer and a first additional spacer, and wherein the first thin spacer has a first edge adjacent the gate and a second edge adjacent the first additional spacer; and
wherein the second gate spacer comprises a second thin spacer and a second additional spacer, and wherein the second thin spacer has a first edge adjacent the gate and a second edge adjacent the second additional spacer.
